(19) United States
(12) Patent Application Publication
(10) Pub. No.: US 2011/0180132 A1
(43) Pub. Date: Jul. 28, 2011

(54) TEXTURING AND DAMAGE ETCH OF SILICON SINGLE CRYSTAL (100) SUBSTRATES

(76) Inventors: Curtis DOVE, Pueblo, CO (US); Greg BAUER, Livermore, CA (US); Mehdi BALOOCH, Berkeley, CA (US)

(21) Appl. No.: 12/695,209

(22) Filed: Jan. 28, 2010

(51) Int. Cl. H01L 31/0236; H01L 21/302; H01L 29/30

(52) U.S. Cl. 136/256; 438/71; 257/618; 257/E21.214; 257/E31.13; 257/E29.106

(57) ABSTRACT

Methods for texturing of single crystal silicon substrates, particularly for use as solar cells or photovoltaic cells. Texturizing of the wafer surface is carried out with a TMAH based solution. The texturizing solution may further include isopropyl alcohol and ethylene glycol at different dilutions in DI water to further improves results.

### FIELD OF THE INVENTION

The present invention relates to the texturing and damage texturing of single crystal silicon (100) substrates, particularly for use as solar cells or photovoltaic cells.

### BACKGROUND OF THE INVENTION

Photovoltaic solar cells are thin silicon disks that can be used to convert sunlight into electricity and serve as an energy source for a wide variety of uses. For example, small area solar cells can be used to power calculators, cell phones and other small electronic devices. Larger panels can be used for supplementing or fulfilling the electrical needs of individual residences, lights, pumping, cooling, heating, etc.

Research into the use of solar energy as a power source began as early as 1839 with the discovery that materials that were sensitive to light could be used to convert sunlight into electricity. An early solar cell, made of gold-coated selenium was produced in 1877, although it was only one percent efficient, i.e. converted only one percent of the incoming sunlight into electricity. Einstein's explanation of the photoelectric effect in 1905 spurred new interest in producing solar electricity at higher efficiencies. However, little progress was made until advances in diodes and transistors allowed silicon solar cells exhibiting four percent efficiency to be produced in 1954. Further work produced solar cells having efficiency up to 15 percent that were used in rural and isolated areas as power sources for a telephone relay system.

In order to meet domestic energy needs, efficiency of solar cells had to be further improved, while maintaining cost effectiveness. Conventional silicon based high efficiency solar cells are produced from single crystalline silicon. In order to make single crystalline silicon wafers, pure silicon starting material must first be obtained. Pure silicon is produced from silicon dioxide of either quartzite gravel or crushed quartz that has been processed in an electric arc furnace to release oxygen and produce carbon dioxide and molten silicon. While this process yields silicon with only one percent impurities, the solar cell industry requires higher purity. One way to produce high purity silicon is to further process the 99 percent pure silicon using a floating zone technique wherein a rod of silicon is passed through a heated zone several times in the same direction. This procedure acts to drag the impurities toward one end of the silicon rod. Once the silicon reaches the desired purity level, the end containing the impurities is removed.

Another method for producing high purity single crystalline wafers is known as the Czochralski method. In this process, a boule of silicon is created, by repeatedly dipping a seed crystal of silicon into melted silicon. As the seed crystal is withdrawn and rotated, a cylindrical ingot, the boule, of single crystalline silicon is formed. This boule is highly pure because impurities tend to remain in the liquid silicon.

Silicon wafers are sliced from the boule one at a time using a single blade circular saw or many at time using a multiwire saw. Slicing results in loss of up to half of the original boule and further cutting may be carried out to shape the wafers into rectangles or hexagons, for fitting together into a solar cell array. The slicing and cutting of the wafers creates roughness and defects caused by saw-damage. These areas of roughness and damage must be removed in order to form an abrupt, defect free p-n junction and contact wires needed for the final solar cell. Roughness and damage is typically removed by an aggressive anisotropic etch process known as “damage etch”.

Several different etch solutions have been proposed and used to perform the damage etch. The most common technique for single crystals uses an etching solution of KOH or NaOH solutions in deionized (DI) water at about 80° C. However, the use of these etching solutions exhibit significant disadvantages. In particular, KOH or NaOH solutions do not wet the silicon surface well, and frequently experience non-uniform hydrogen bubble buildup that prevents uniform contact between the silicon surface and the etching solution. This can result in non-uniform etching across the wafer, which leads to variation in solar cell efficiency and lower reproducibility of the solar cell product. In addition, the KOH or NaOH leave potassium or sodium contaminants on the surface of the substrate that can not easily be removed by rinsing in deionized water. These contaminants also reduce the efficiency of the product solar cells.

Other solutions have been used to etch silicon, but have not been suggested for use in solar cell “damage etch” processes. Rather, tetramethylammonium hydroxide (TMAH), isopropyl alcohol (IPA) and pyrazine have been used to etch silicon for use in MEMS etching applications. These solutions provide an etch that obtains a flat surface with minimal undercutting of mask layers. (see Chung, Anisotropic Etching Characteristics of Si in Tetramethylammonium Hydroxide: Isopropyl Alcohol: Pyrazine Solutions, Journal of the Korean Physical Society, Vol. 46, No. 5, May 2005, pp. 1152-1156).

In co-pending U.S. patent application Ser. No. 12/366,141 the use of TMAH as an alternative to KOH or NaOH for performing the damage etch is disclosed. As shown in this patent application, the use of TMAH results in improved uniformity and reduced surface roughness of the silicon substrate. TMAH provides good wetting of the silicon wafer surface, unlike the KOH or NaOH solutions used in the prior art and therefore when TMAH is used as the damage etch solution, a stronger, more resilient wafer is produced. Further, the resultant wafer is better prepared to withstand the texturing etch process.

The result of the damage etch process is a silicon wafer that is very shiny and reflective. The efficiency of a solar cell is determined by the ability to gather or absorb light. While silicon has a large absorption coefficient in the visible light spectrum, it also exhibits a high reflection coefficient. To increase efficiency of solar cells, the reflectivity of the damage etched silicon wafer must be reduced. One common method of reducing reflectance is to coat the silicon wafer with an anti-reflective coating (ARC), such as silicon oxide, silicon nitride or titanium dioxide. However, these films exhibit resonance structures that limit their effectiveness to a small range of angles and wavelengths, such that efficiency depends on the angle of incidence of the light.

Another method of reducing reflectance and improving solar cell efficiency is to texture the silicon wafer surface using a wet-chemical etch to from pyramidal structures. These structures provide higher levels of light trapping based on geometrical optics, e.g. the texturing is on a scale equal to or greater than optical wavelengths of the incident light causing the incident light to reflect multiple times and thereby enhance absorption.

The texturing process is generally carried out using a mixture of KOH or NaOH and IPA in DI water as the etchant. (See U.S. Pat. No. 3,998,659; Gangopadhyah et al, A novel low cost texturization method for large area commercial mono-crystalline silicon solar cells, Solar Energy Materials & Solar Cells, 90, 2006, pp. 3557-3567; King et al., Proceedings of 22^{nd} IEEE International Photovoltaic Specialists Conference, Las Vegas, 1991, pp. 303-308). The addition of IPA serves to mask specific silicon sites, preventing etching by the solution, to thereby form the pyramidal structures because of the high selectivity of KOH dissolution of silicon for different crystallographic orientations. It has also been reported that a combination of IPA and aqueous alkaline ethylene glycol resulted in more uniform pyramidal texturing on highly polished silicon (100) for use in semiconductor electronic applications. (See U.S. Pat. No. 6,451,218). In addition, the use of sodium acetate, anhydrous (CH₃COONa) operates in a similar manner to IPA for alkaline texturing, however the two compounds can not co-exist. (see Zhenqiang Xi et al, Investigation of texturization for monocrystalline silicon solar cells with different kinds of alkaline, Renewable Energy 29, 2004, pp. 2101-2107). In none of the references noted above has the use of the solutions mentioned been applied to as-cut silicon wafers for purposes of texturing a sample that still has saw damage and contamination.

In co-pending U.S. patent application Ser. No. 12/366,141 mentioned above, the texturing stage is carried out with a mixture of KOH or NaOH and isopropyl alcohol (IPA) in DI water as the etchant. The resulting pyramidal structures are very uniform and exhibit desirable low reflectance values. Further, as disclosed in this patent application, by substitution of a portion of the IPA with Ethylene Glycol (EG), better surface wetting is achieved, resulting in even lower reflectance. Also, the EG is less volatile than IPA and helps improve operational consistency of the chemical bath because of less evaporation loss.

Because the texturing step is done prior to deposition of an anti-reflection coating, commonly, a silicon nitride film, it is profoundly important that no metal contaminants are left behind on the wafer surface that may act as electron-hole recombination centers. Conventional DI rinse cannot alone eliminate the surface build-up of alkaline metal residue when KOH or NaOH is used in the texturing process. The metal contaminants act as electron-hole recombination sites which reduce the minority carrier lifetime of the solar cell and also reduce solar cell efficiency.

Therefore, there remains a need in the art for improvements to the texturing and damage etch of single crystal silicon substrates, particularly for use in solar cells.

### SUMMARY OF THE PRESENT INVENTION

The present invention provides improved methods for performing damage etch and texturing of single crystal silicon substrates, particularly for use as solar cells or photovoltaic cells. In particular, the present invention performs surface texturing using a solution of Tetramethylammonium hydroxide ((CH₃)₄NOH) (TMAH) and IPA or IPA and EG and DI water to replace the conventional KOH or NaOH solutions used in the prior art.

### BRIEF DESCRIPTION OF THE DRAWINGS

FIG. 1 is an atomic force microscopy (AFM) view of the surface of an as-cut single crystalline silicon wafer.

FIG. 2 is an AFM view of the surface of a single crystalline silicon wafer following damage etch using a KOH based etch solution.

FIG. 3 is an AFM view of the surface of a single crystalline silicon wafer following damage etch using a TMAH based etch solution.

FIG. 4 is an AFM view of a single crystalline silicon wafer following damage etch with a KOH based etch solution and texturing using a TMAH based solution in accordance with an embodiment of the present invention.

FIG. 5 is an AFM view of a single crystalline silicon wafer following damage etch with a TMAH based etch solution and texturing using a TMAH based solution in accordance with an embodiment of the present invention.

FIG. 6 is a graph showing reflectance values for the silicon wafer processed in accordance with an embodiment of the present invention.

FIG. 7 is a graph showing reflectance values for the silicon wafer processed in accordance with an embodiment of the present invention.

### DETAILED DESCRIPTION OF THE INVENTION

The present invention sets forth improved methods for carrying out damage etch and texturing of single crystal silicon substrates. These silicon substrates are particularly useful as solar cells or photovoltaic cells.

In accordance with the present invention, texturing of the wafer is done with a solution comprising a mixture of Tetramethylammonium hydroxide ((CH₃)₄NOH) (TMAH) mixed with IPA and Di water or mixed with a combination of IPA, EG and DI water. The use of TMAH as the texturing solution results in extremely uniform pyramidal structures with very low reflectance values and with excellent wettability. The TMAH may be mixed with IP or with IP and EG together to improve pyramidal structure formation. In general the pyramidal structure obtained this way is smaller and more uniform than that obtained from KOH or NaOH solutions. As a result the absorption of sun light in the UV spectrum is higher.

The texture etch may be carried out according to the present invention following damage etch using either traditional KOH and DI solution or the TMAH and DI solutions described in the co-pending patent application noted above. In either case, the damage etch provides a relatively smooth and uniform wafer surface, although as shown in the prior patent application, improved smoothness and uniformity are obtained with the TMAH and DI damage etch solution.

Using the TMAH and DI texture solution avoids metal contamination of the wafer surface that occurs when using KOH and DI as the damage etch solution. In particular, the TMAH and DI texture solution etches away only a few micrometers of the silicon near the substrate, removing any potassium residue that may be left behind on the wafer surface from using a KOH and DI damage etch solution. As noted above, this metal contamination can not be effectively removed by a DI rinse alone and often leads to electron-hole recombination sites that reduce the minority carrier lifetime of the solar cell. However, the present invention overcomes this problem because the potassium residue can be eliminated by using a TMAH based solution as the texturing chemical. This elimination of potassium surface residue is essential for improving the efficiency of solar cells and serves to eliminate the possibility of electron-hole recombination sites. Further, TMAH has good etching characteristics and produces very little device contamination.

A further improvement of the present invention is that texturing using a TMAH solution creates smaller pyramids, on the order to 1-2 μm on the textured surface than those that can be achieved when using a KOH solution, on the order of 5-10 μm. This is extremely beneficial to the efficiency of the final solar cell because the visible light spectrum has wavelengths less than 1 μm, such that the ability to trap light is increased by a TMAH textured surface as compared to a KOH. In addition, smaller pyramidal texturing better facilitates contacting to bus bars and helps to improve efficiency of the solar cell product.

As noted, the texturing solution of the present invention may be a solution of TMAH and IPA. In a further embodiment of the present invention, at least half of the IPA can be replaced with EG to provide increased wetting of the silicon surface and provide increased benefits as noted above. Further, using ethylene glycol in the mixture allows for lower reflectance values can be achieved while the solution is also less expensive and less volatile. This is at least in part because IPA has a very low boiling point and some IPA is lost through evaporation during the process. The texturing solution according to the present invention also has the following benefits over traditional KOH solutions; less hazardous waste is produced, greater duration of use for the solutions in situ is possible and surface topography, morphology and uniformity are optimized. In particular, texturing chemicals of the present invention are more environmentally friendly, are less dangerous to work with and require a lower quantity for the same result than possible with the prior art chemicals. In addition, solar cells produced using the etch solutions according to the present invention have greater uniformity and exhibit lower reflectance of light throughout the light range from UV to IR and thus have higher efficiencies.

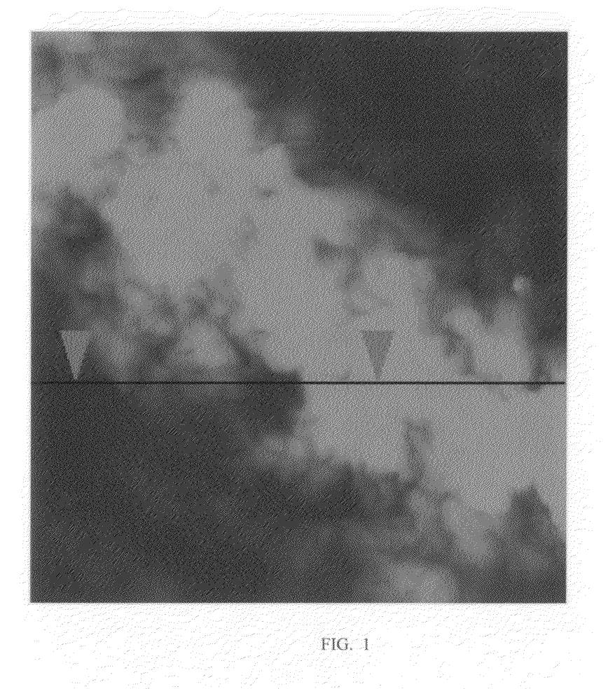

Some results achieved by using the present invention are shown in FIGS. 1 through 7. In particular, FIG. 1 is an atomic force microscopy (AFM) view of the surface of an as-cut single crystalline silicon wafer showing macro-roughness troughs of 10 μm or more in height as well as local micro-roughness of less than a micron. As noted above, this roughness as well as contaminants, e.g. abraded metal from the saw wire and grinding abrasive, must be removed for the wafer to be useful as a solar cell, i.e. by performing damage etch. In addition, the as-cut wafers may contain micro-cracks which must be removed by the damage etch in order to increase fracture toughness.

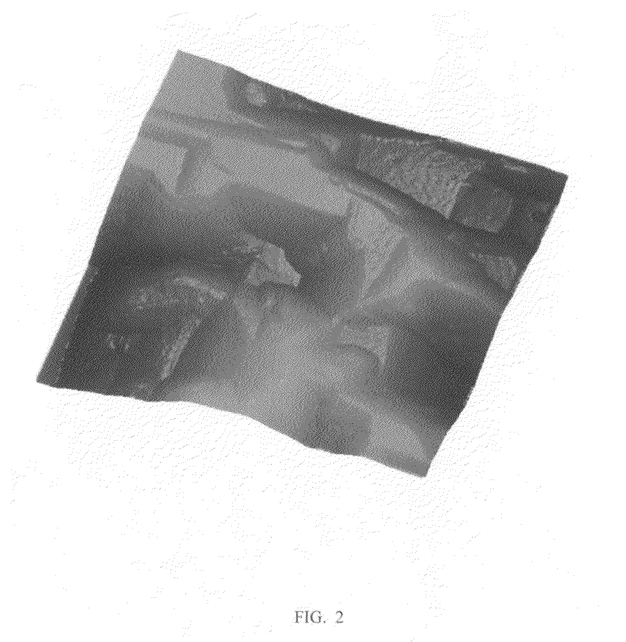

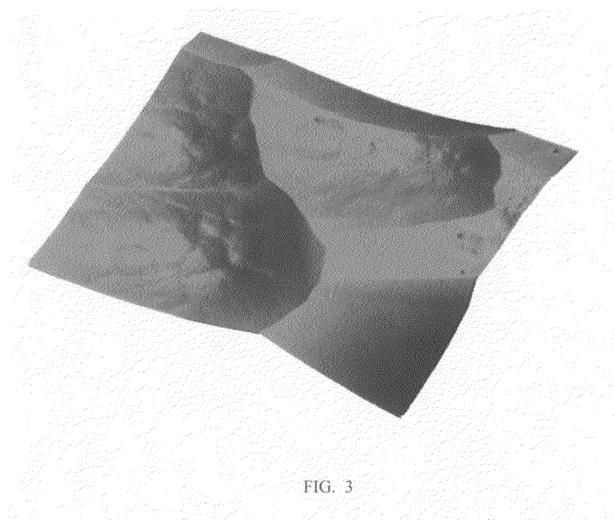

Damage etch is then carried out to create a smooth wafer surface and to remove contaminants. FIG. 2 is an AFM view of the surface of a single crystalline silicon wafer following damage etch using a KOH based solution (e.g. 45% KOH/DI) and FIG. 3 is an AFM view of the surface of a single crystalline silicon wafer following damage etch using a TMAH based solution (e.g. 12.5% TMAH/DI). In either case, the damage-etch removed micro-roughness completely and reduced the macro-roughness to a fraction of a micron, as well as removing most of the abraded contaminants (FIGS. 2 and 3). This results in a very uniform and smooth surface for texturization. One disadvantage of the use of a KOH based solution for damage etch is that potassium residue is left on the wafer surface that must be removed before processing as a solar cell.

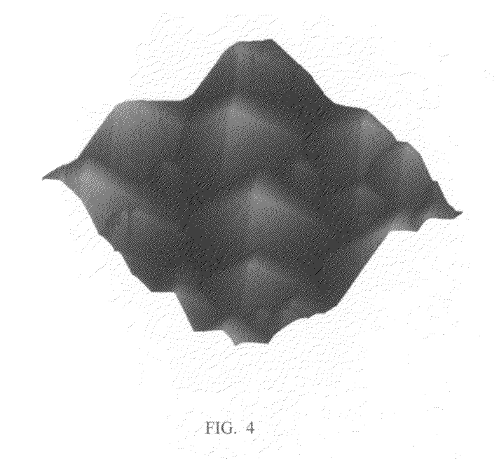

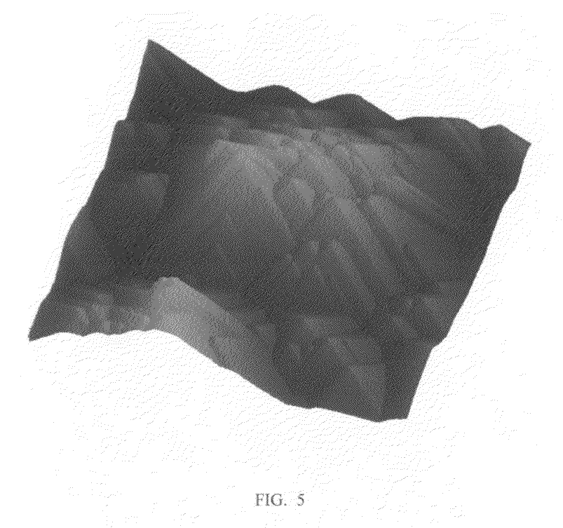

Texturing is then carried out using the TMAH based solution according to the present invention. FIG. 4 is an AFM view of a single crystalline silicon wafer that has been damage etched using a KOH based solution followed by texturing of the surface using the TMAH based solution of the present invention. FIG. 5 is an AFM view of a single crystalline silicon wafer that has been damage etched using a TMAH based solution followed by texturing of the surface using the TMAH based solution of the present invention. In both cases, extremely uniform pyramidal structures are formed across the wafer. The TMAH texturing solution may include IPA and preferably is a solution of TMAH, IPA and EG in DI (e.g. 12.5% TMAH, 4% IPA, 1% EG in DI). In particular, by replacing half of the IPA with EG, the reflectance of the wafer surface is reduced in the visible range to below 8% with consistent uniformity.

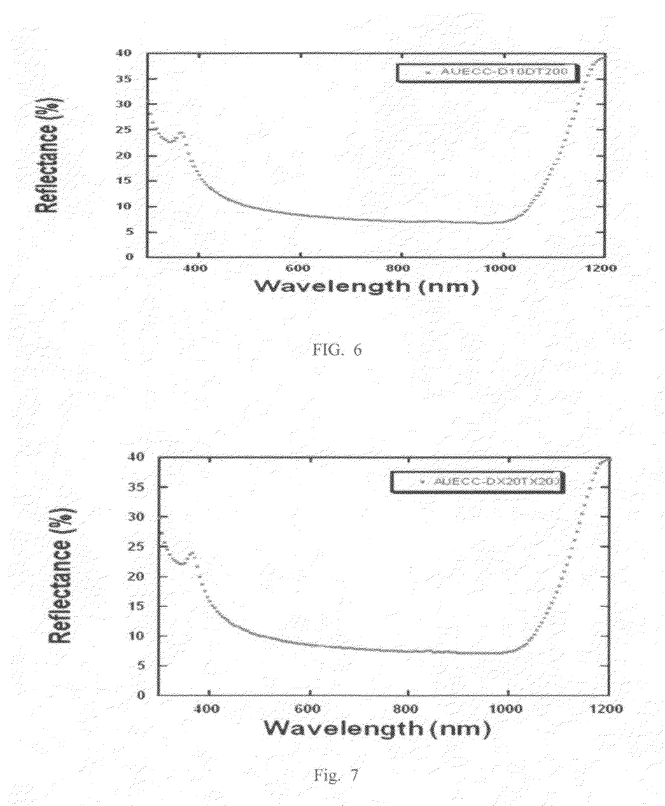

FIG. 6 is a graph showing the reflectance of the wafer following KOH damage etched and TMAH/IPA/EG texturing. FIG. 7 is a graph showing the reflectance of the wafer following TMAH damage etch and TMAH/IPA/EG texturing. In either case, the exceptional results achieved by the present invention are evident.

While the present invention has been described particularly with respect to the production of solar cells, similar methods will be useful in other device production, such as MEMS and semiconductor processing for integrated circuits. It is anticipated that other embodiments and variations of the present invention will become readily apparent to the skilled artisan in the light of the foregoing description, and it is intended that such embodiments and variations likewise be included within the scope of the invention as set out in the appended claims.

What is claimed:

1. A method of texturizing the surface of a single crystal silicon surface comprising:
treating the single crystal silicon surface with a tetramethylammonium hydroxide solution.

2. The method of claim 1 wherein the silicon surface is the surface of a single crystal silicon wafer for use in a photovoltaic or solar cell device.

3. A method of forming a semiconductor device comprising:
providing a single crystal silicon wafer having damage on a surface thereof;
treating the wafer with an etching solution to remove the damage; and
treating the wafer with a tetramethylammonium hydroxide texturing solution to form pyramidal structures on the wafer.

4. A method of claim 3 wherein the damage is caused by saw cutting.

5. The method of claim 3 wherein the semiconductor device is a photovoltaic or solar cell device.

6. The method of claim 3 wherein the etching solution is a tetramethylammonium hydroxide etching solution or a potassium hydroxide etching solution.

7. The method of claim 6 wherein the tetramethylammonium hydroxide etching solution is a 45% tetramethylammonium hydroxide in deionized water solution.

8. The method of claim 3 wherein the tetramethylammonium hydroxide texturizing solution also includes isopropyl alcohol or isopropyl alcohol and ethylene glycol.

9. The method of claim 8 wherein the tetramethylammonium hydroxide texturizing solution is a 12.5% tetramethylammonium hydroxide, 4% isopropyl alcohol, 1% ethylene glycol in deionized water solution.

10. A solar cell device that is manufactured by a process including a texturizing step using a tetramethylammonium hydroxide solution.

11. The solar cell if claim 10 wherein the tetramethylammonium hydroxide solution includes isopropyl alcohol or isopropyl alcohol and ethylene glycol.

12. A silicon wafer having a textured surface formed by a process using a tetramethylammonium hydroxide solution.

13. The silicon wafer of claim 12 wherein the tetramethylammonium hydroxide solution includes isopropyl alcohol or isopropyl alcohol and ethylene glycol.

14. The silicon wafer of claim 12 wherein the wafer is a single crystal silicon wafer.
